(19) United States
(12) Patent Application Publication
(10) Pub. No.: US 2025/0043421 A1
(43) Pub. Date: Feb. 6, 2025

(54) VALVE SYSTEMS FOR BALANCING GAS FLOW TO MULTIPLE STATIONS OF A SUBSTRATE PROCESSING SYSTEM

(71) Applicant: LAM RESEARCH CORPORATION, Fremont, CA (US)

(72) Inventors: Michael Philip ROBERTS, Tigard, OR (US); Bharath Kumar SEETHARAMA, Bangalore (IN); Ryan BLAQUIERE, Portland, OR (US)

(21) Appl. No.: 18/715,203

(22) PCT Filed: Dec. 7, 2022
(86) PCT No.: PCT/US2022/052113

§ 371 Date: May 31, 2024

Related U.S. Application Data
(60) Provisional application No. 63/288,794, filed on Dec. 13, 2021.

(51) Int. Cl. C23C 16/455; C23C 16/52

(52) U.S. Cl. CPC C23C 16/45544; C23C 16/45561; C23C 16/52

(57) ABSTRACT

A substrate processing system includes N valve systems connected to N stations, respectively. Each valve system includes a manifold block, a plurality of valves, and a flow control device. The manifold block includes inlets to receive a process gas and an inert gas, an outlet connected to a station, and a plurality of gas flow channels disposed within the manifold block and connected to the inlets and the outlet. The valves are mounted to the manifold block and control flow of the process gas and the inert gas through the outlet. The flow control device is mounted to the manifold block and controls flow of the inert gas through the manifold block into the one of the N stations. The flow control device of each of the N valve systems is calibrated to balance the flow of the inert gas in the N stations.

### CROSS-REFERENCE TO RELATED APPLICATIONS

This application claims the benefit of U.S. Provisional Application No. 63/288,794, filed on Dec. 13, 2021. The entire disclosure of the above application is incorporated herein by reference.

### FIELD

The present disclosure relates generally to substrate processing systems and more particularly to valve systems for balancing gas flow to multiple stations of a substrate processing system.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system typically comprises a plurality of stations (also called processing chambers or process modules) that perform deposition, etching, and other treatments on substrates such as semiconductor wafers. Examples of processes that may be performed on a substrate comprises a chemical vapor deposition (CVD) process, a chemically enhanced plasma vapor deposition (CEPVD) process, a plasma enhanced chemical vapor deposition (PECVD) process, a sputtering physical vapor deposition (PVD) process, atomic layer deposition (ALD), and plasma enhanced ALD (PEALD). Additional examples of processes that may be performed on a substrate comprise, but are not limited to, etching (e.g., chemical etching, plasma etching, reactive ion etching, atomic layer etching (ALE), plasma enhanced ALE (PEALE), etc.) and cleaning processes.

During processing, a substrate is arranged on a substrate support such as a pedestal in a station. During deposition, gas mixtures comprising one or more precursors are introduced into the station, and plasma may be optionally struck to activate chemical reactions. During etching, gas mixtures comprising etch gases are introduced into the station, and plasma may be optionally struck to activate chemical reactions. A computer-controlled robot typically transfers substrates from one station to another in a sequence in which the substrates are to be processed.

Atomic layer deposition (ALD) is a thin-film deposition method that sequentially performs a gaseous chemical process to deposit a thin film on a surface of a material (e.g., a surface of a substrate such as a semiconductor wafer). Most ALD reactions use one or more chemicals called precursors (reactants) that react with the surface of the material in a sequential, self-limiting manner. Steps in which the precursors are supplied are called dose steps. Typically, a purge step is performed between two successive dose steps. Through repeated exposure to precursors, a thin film is gradually deposited on the surface of the material. Thermal ALD (T-ALD) is carried out in a heated processing chamber. The processing chamber is maintained at a sub-atmospheric pressure using a vacuum pump and a controlled flow of an inert gas. The substrate to be coated with an ALD film is placed in the processing chamber and is allowed to equilibrate with the temperature of the processing chamber before starting the ALD process. Atomic layer etching comprises a sequence that alternates between self-limiting chemical modification steps and etching steps. The chemical modification steps affect only top atomic layers of the substrate. The etching steps remove only the chemically-modified areas from the substrate. The sequence allows removal of individual atomic layers from the substrate.

### SUMMARY

A substrate processing system comprises N stations and N valve systems, where N is an integer greater than 1. The N stations are configured to perform a process on substrates. The N valve systems are connected to the N stations, respectively. Each of the N valve systems comprises a manifold block, a plurality of valves, and a flow control device. The manifold block comprises inlets to receive a process gas and an inert gas, an outlet connected to one of the N stations, and a plurality of gas flow channels disposed within the manifold block and connected to the inlets and the outlet. The plurality of valves is mounted to the manifold block and is configured to control flow of the process gas and the inert gas through the outlet. The flow control device is mounted to the manifold block and is configured to control flow of the inert gas through the manifold block into the one of the N stations. The flow control device of each of the N valve systems is calibrated to balance the flow of the inert gas in the N stations.

In other features, the flow control device includes a 2-port valve, and a flow coefficient of the 2-port valve in each of the N valve systems is calibrated to balance the flow of the inert gas in the N stations.

In other features, the flow control device includes a flow-through cap-and-orifice assembly, and an orifice in the flow-through cap-and-orifice assembly is designed to balance the flow of the inert gas in the N stations.

In another feature, the substrate processing system further comprises a controller configured to calibrate the flow control device in each of the N valve systems to balance the flow of the inert gas in the N stations.

In other features, the substrate processing system further comprises N sensors and a controller. The N sensors are configured to sense gas flow from the N valve systems into the N stations, respectively. The controller is configured to calibrate the flow control device in at least one of the N valve systems based on data received from at least one of the N sensors to balance the flow of the inert gas in the N stations.

In other features, the substrate processing system further comprises a metrology system and a controller. The metrology system is configured to analyze one or more of the substrates processed in one or more of the N stations. The controller is configured to calibrate the flow control device in at least one of the N valve systems based on data received from the metrology system to balance the flow of the inert gas in the N stations.

In other features, the manifold block comprises a second outlet, and one of the valves is configured to selectively divert one or more gases from the manifold block through the second outlet during a step of the process.

In another feature, the flow control device in each of the N valve systems is configured to control the flow of the inert gas that is supplied to each of the N stations at a plurality of flow rates.

In another feature, the flow control device in each of the N valve systems is configured to control the flow of the inert gas that is supplied to each of the N stations uninterruptedly at a first rate and periodically at a second rate greater than the first rate.

In other features, the valves comprise a 4-port valve and a 2-port valve, and the flow control device comprises a 2-port valve.

In other features, the valves comprise a 4-port valve and a 2-port valve, and the flow control device comprises a flow-through cap-and-orifice assembly.

In other features, the process includes an atomic layer deposition process, and the flow control device is configured to control the flow of the inert gas during dose and purge steps of the atomic layer deposition process.

In still other features, a substrate processing system comprises N stations, N valve systems, and a controller, where N is an integer greater than 1. The N stations are configured to perform a process on substrates. The N valve systems are connected to the N stations, respectively. Each of the N valve systems comprises a manifold block, a plurality of valves, and a flow control device. The manifold block comprises inlets to receive a process gas and an inert gas, an outlet connected to one of the N stations, and a plurality of gas flow channels disposed within the manifold block and connected to the inlets and the outlet. The plurality of valves is mounted to the manifold block and configured to control flow of the process gas and the inert gas through the outlet. The flow control device is mounted to the manifold block and is configured to control flow of the inert gas through the manifold block into the one of the N stations. The controller is configured to calibrate the flow control device in each of the N valve systems to balance the flow of the inert gas in the N stations during dose and purge steps of the atomic layer deposition process.

In other features, the flow control device includes a 2-port valve, and a flow coefficient of the 2-port valve in each of the N valve systems is calibrated to balance the flow of the inert gas in the N stations.

In other features, the flow control device includes a flow-through cap-and-orifice assembly, and an orifice in the flow-through cap-and-orifice assembly is designed to balance the flow of the inert gas in the N stations.

In other features, the substrate processing system further comprises N sensors configured to sense gas flow from the N valve systems into the N stations, respectively. The controller is configured to calibrate the flow control device in at least one of the N valve systems based on data received from at least one of the N sensors to balance the flow of the inert gas in the N stations.

In another feature, the substrate processing system further comprises a metrology system configured to analyze one or more of the substrates processed in one or more of the N stations. The controller is configured to calibrate the flow control device in at least one of the N valve systems based on data received from the metrology system to balance the flow of the inert gas in the N stations.

In other features, the manifold block comprises a second outlet, and one of the valves is configured to selectively divert one or more gases from the manifold block through the second outlet during the purge step of the atomic layer deposition process.

In another feature, the flow control device in each of the N valve systems is configured to control the flow of the inert gas that is supplied to each of the N stations at a plurality of flow rates during the dose and purge steps.

In another feature, the flow control device in each of the N valve systems is configured to control the flow of the inert gas that is supplied to each of the N stations uninterruptedly at a first rate during the dose step and purge steps and at a second rate greater than the first rate during the purge step.

In other features, the valves comprise a 4-port valve and a 2-port valve, and the flow control device comprises a 2-port valve or a flow-through cap-and-orifice assembly.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIGS. 1A and 1B show examples of substrate processing systems (tools) comprising a plurality of stations and respective valve systems according to the present disclosure;

FIG. 1C shows one of the stations, associated valve system comprising three valves, and other components of the tools shown in FIGS. 1A and 1B in further detail;

FIGS. 2A and 2B show an example a valve system comprising two-valves;

FIGS. 3A and 3B show an example of the valve systems shown in FIGS. 1A-1C in further detail;

FIGS. 4A and 4B show examples of a manifold block used in the valve systems of FIGS. 1A-1C;

FIG. 5 shows an example of a flow-through cap-and-orifice assembly that can be used instead of the third valve in the valve systems of FIGS. 1A-1C;

FIGS. 6A and 6B show an example of the valve system shown in FIGS. 1A-1C comprising the flow-through cap-and-orifice assembly of FIG. 5; and

FIG. 7 shows a method for balancing gas flow in the stations of the tools shown in FIGS. 1A-1C using the valve systems shown in FIGS. 3A-6B.

In the drawings, reference numbers may be reused to identify similar and/or identical elements.

### DETAILED DESCRIPTION

A substrate processing system (also called a tool) comprises a plurality of stations (also called process modules or processing chambers). The tool comprises a gas delivery system that delivers various gases to the stations via various gas flow paths. Non-limiting examples of the gases include process gases, carrier gases, precursor gases, purge gases, cleaning gases, and so on. The gas flow paths are defined by conduits, valves, and manifold blocks.

The gas delivery system uses a valve system to control the flow of the various gases into the stations. For example, in tools in which atomic layer deposition (ALD) is performed on substrates in multiple stations, each station typically uses a valve system comprising two valves. A first valve is used to supply a precursor to the station during a dose step of a process. A second valve is used to divert residual precursor from the station during a purge step of the process. The second valve prevents the residual precursor from entering the station during the purge step.

In addition, an inert gas is supplied to each station during the process. The inert gas is typically supplied to each station through two manifolds. The inert gas is supplied to the station through a first manifold throughout the process at a relatively low flow rate (a first flow rate). The supply of the inert gas at the low first flow rate is called a trickle supply. Additionally, the inert gas is periodically supplied to the station (e.g., between two dose steps) through a second manifold at a higher flow rate (a second flow rate) than the first flow rate during the purge step. The supply of the inert gas at the higher second flow rate, which is in addition to the trickle supply, is called a burst supply.

Presently, other than using an on-off valve, no flow control is employed in supplying the inert gas to the stations via these manifolds. Accordingly, the flow of inert gas into the stations is not regulated except that the flow of inert gas into the stations is turned on or off. Further, the flow of inert gas is not balanced across the stations due to manufacturing variations in the components of the gas distribution system.

Gas flow imbalance between the stations can cause various problems. For example, when plasma is struck in a station during a process, undesirable plasma instability can occur. Further, the plasma instability differs from one station to another due to flow imbalance between the stations. Typically, a process is performed according to parameters specified for the process. However, the specified process parameters can be close to values that cause undesirable plasma instability. With the addition of flow imbalance, the undesirable plasma instability can occur in one or more stations. Without flow balancing, to avoid plasma instability, process parameters need to be specified far enough from the unstable regime to avoid plasma instability in any station. Specifying process parameters far enough from the unstable regime may require wide deviation from the optimal process parameters.

Ideally, such deviations could be varied from station to station depending on the flow imbalance between the stations. Practically, however, such deviations cannot be varied from station to station, at least not in a controlled manner, since ISO standards require using the same deviations on all tools and all stations, which cannot account for hardware variability. Thus, without flow balancing, a single deviation that is large enough for worst case is typically used, which can be significant and therefore undesirable on an unbalanced design. Instead, with flow balancing, the deviations can be minimized, and the process can be performed with optimal parameter values that are close to the specified process parameters and that make plasma instability uniform across the stations.

The present disclosure provides a flow control knob in the form of a controllable third valve to regulate the flow of inert gas during both trickle and burst supplies from the two manifolds into each station. The flow of inert gas through the third valve into each station can be individually controlled such that the flow of inert gas to all of the stations is balanced. The flow coefficients (Cᵥ, explained below) of the third valves through which the inert gas is supplied to the stations can be calibrated to compensate for manufacturing variations in the gas distribution systems. The flow coefficients of the third valves can be calibrated during manufacturing, installation, and/or the life of the tool (e.g., during preventive maintenance). Alternatively, a flow-through cap-and-orifice assembly (hereinafter the cap and orifice assembly) can be used instead of the third valve to regulate the flow of inert gas into each station. An orifice of the cap and orifice assembly for each station can be sized according to a known Cᵥ requirement for the station to balance the flow of inert gas to all of the stations in the tool.

The first valve used to supply the precursor to the station during the dose step, the second valve used to divert the precursor during the purge step, and the third valve (or the cap and orifice assembly) used to regulate the flow of inert gas into the station are mounted to a manifold block. The manifold block includes inlets to receive the precursor and the inert gas from the respective manifolds. The manifold block includes outlets to supply the gases to the station during the dose step and to divert gases from the station during the purge step. The manifold block includes multiple gas flow channels that are connected to the valves, the inlets, and the outlets. The gas flow channels are designed to minimize dead leg (i.e., stagnation of gases in the gas flow channels). In addition, one or more controllable heaters can be disposed in the manifold block to prevent condensation around the gas flow channels. A set of the first, second, and third valves and the manifold block (called a valve system) supplies the various gases to a showerhead in a station. A separate valve system is used with each station.

Further, feedback from one or more sensors located downstream from the valve system can be used to control the flow of inert gas through the third valve (or the cap and orifice assembly) to each station to achieve station-to-station gas flow balance. For example, such feedback may be received from sensors located in the showerhead and/or the station. Alternatively or additionally, feedback from a metrology system associated with the tool can be used to achieve station-to-station gas flow balance. For example, such feedback may include data collected by the metrology system from substrates processed in the stations, which can indicate process variations caused by gas flow balance. These and other features of the valve system of the present disclosure are described below in further detail.

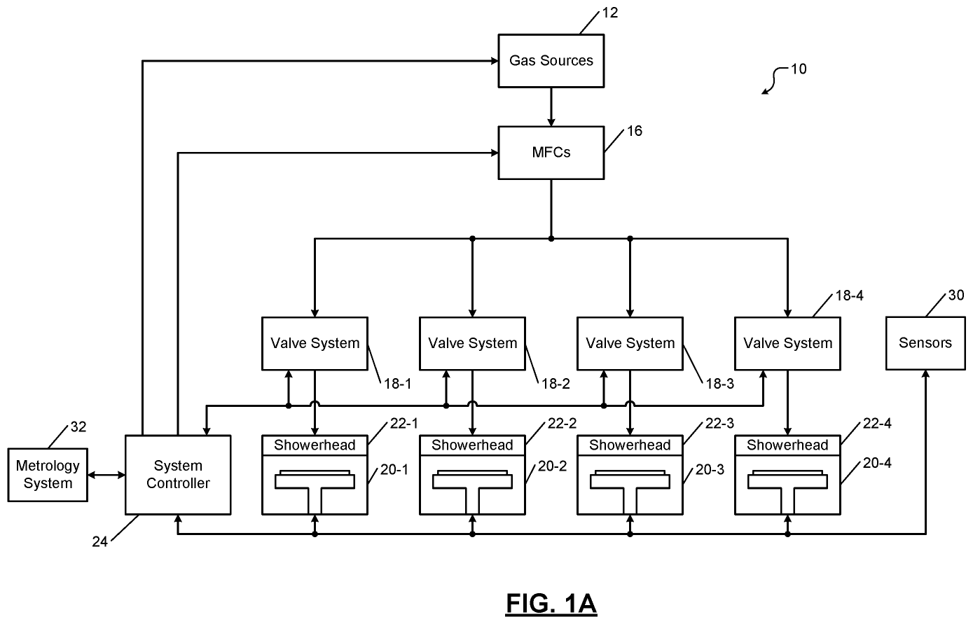

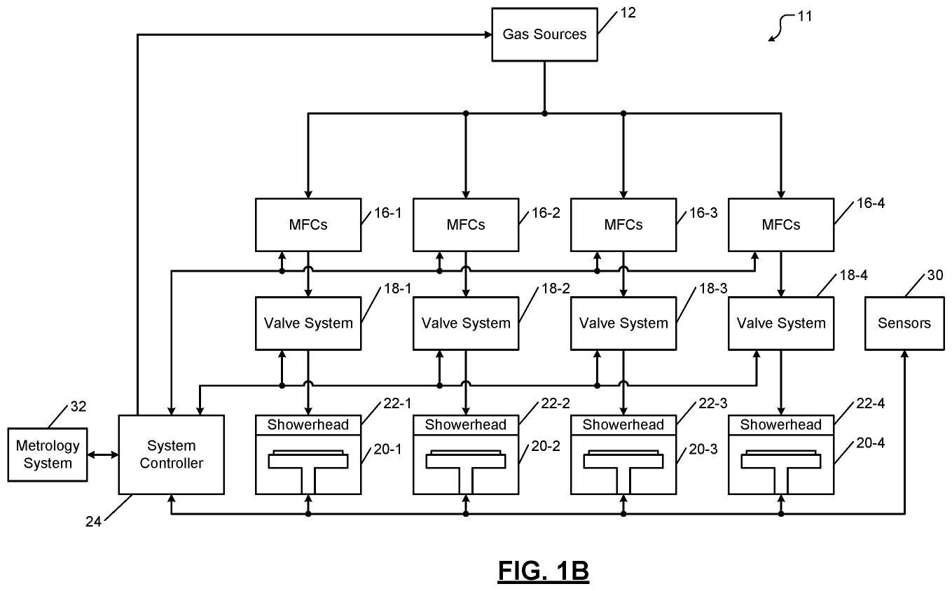

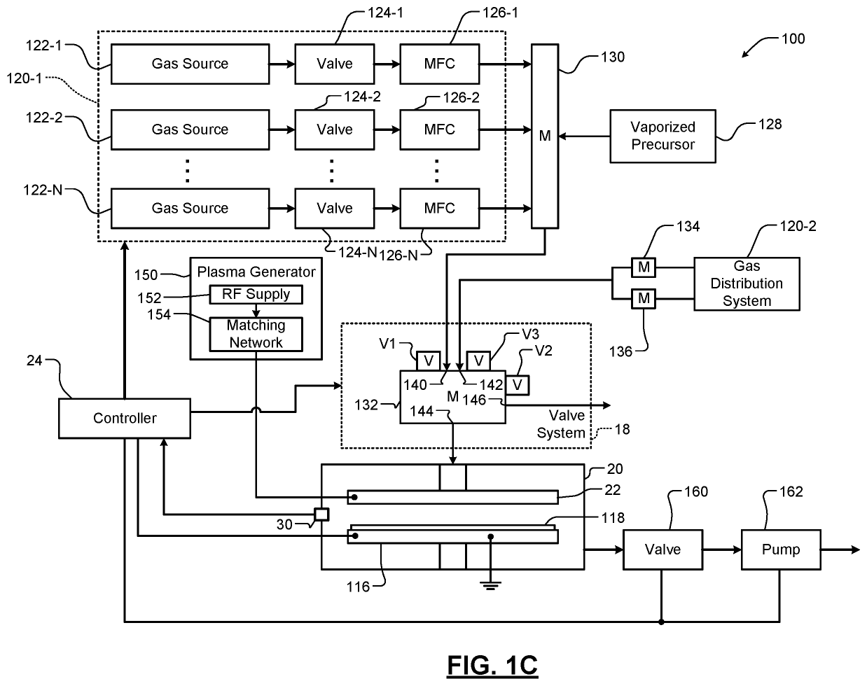

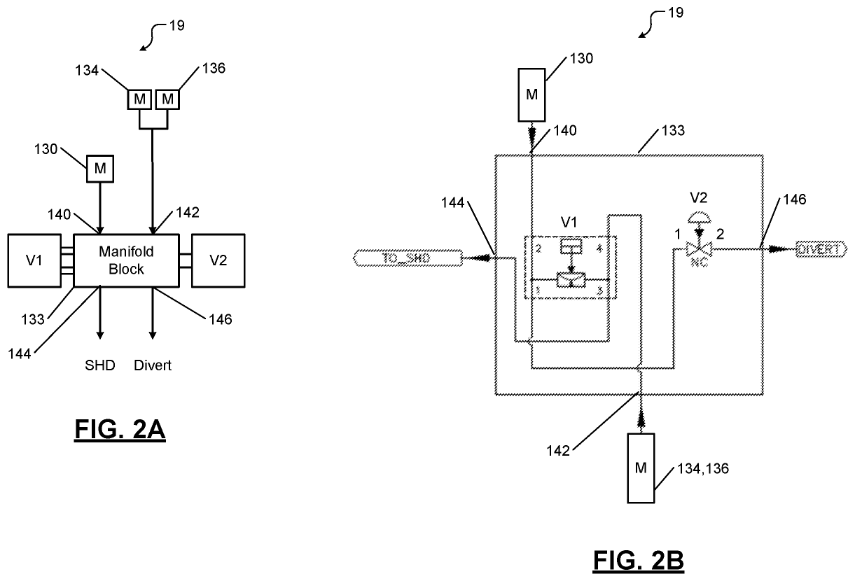

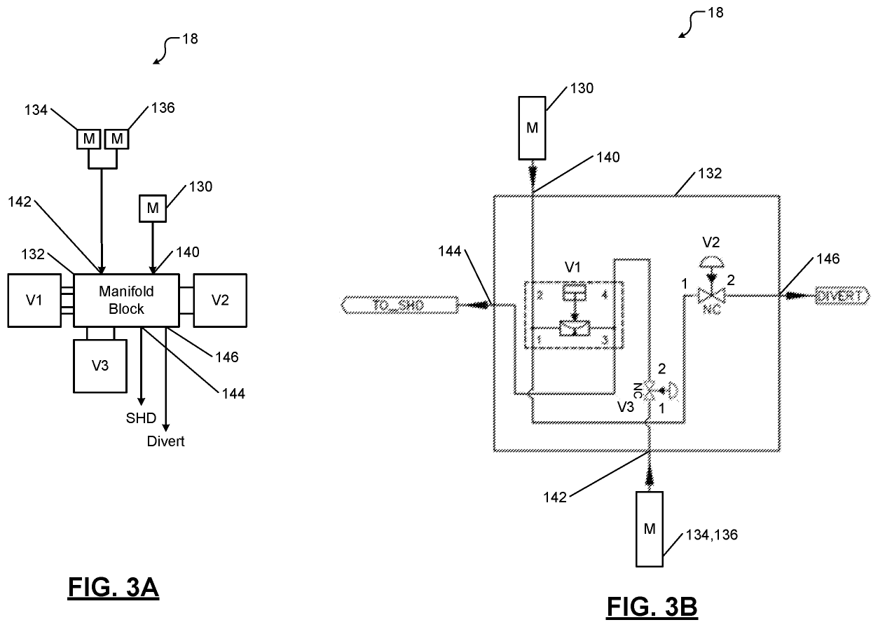

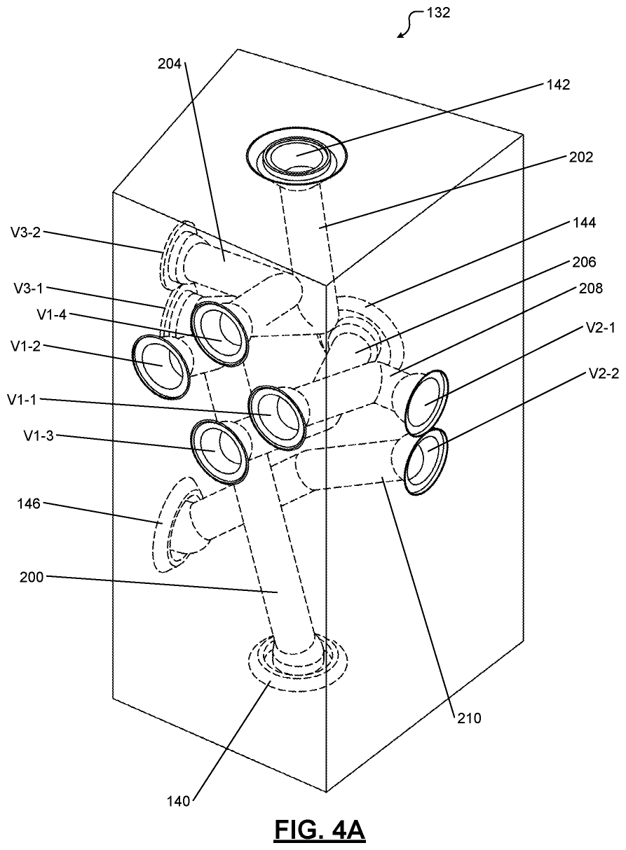

Before describing the valve system in detail, various non-limiting examples of tool configurations are initially shown and described with reference to FIGS. 1A-1C. These examples show tools comprising different gas delivery systems in which the valve system of the present disclosure comprising three valves can be used. For completeness, an example of a two-valve system, which does not control the flow of inert gas as the valve system of the present disclosure does, is shown and described with reference to FIGS. 2A and 2B. Subsequently, the valve system of the present disclosure is described in detail with reference to FIG. 3A onwards.

FIGS. 1A-1C show examples of different tool configurations employing the valve system of the present disclosure. FIG. 1A shows an example of a tool 10 with mass flow controllers (MFCs) that are common to the stations. FIG. 1B shows an example of a tool 11 with separate MFCs for each station. FIG. 1C shows another example of a tool 100 employing the valve system of the present disclosure, where the valve system and other components of the gas distribution system and the tool are shown in further detail. While FIG. 1C shows the details for only one station, it is understood that other stations in the tool use similar setup.

In FIG. 1A, the tool 10 comprises gas sources 12. The gas sources 12 supply various gases including but not limited to precursors, reactants, inert gases, purge gases, cleaning gases, and other gases. The tool 10 comprises a set of MFCs 16. The MFCs 16 control mass flow of the gases supplied by the gas sources 12. The MFCs 16 supply the gases from the gas sources 12 to a plurality of valve systems 18-1, 18-2, 18-3, and 18-4 (collectively the valve systems 18) through various manifolds (shown in FIG. 1C). Examples of the valve systems 18 are shown and described in detail with reference to FIG. 3A onwards.

The tool 10 comprises a plurality of stations 20-1, 20-2, 20-3, and 20-4 (collectively the stations 20). The stations 20 respectively comprise showerheads 22-1, 22-2, 22-3, and 22-4 (collectively the showerheads 22). The valve systems 18 are respectively connected to the showerheads 22. The valve systems 18 supply the gases supplied by the gas sources 12 to the respective stations 20 via the respective showerheads 22. The valve systems 18 supply the gases to the stations 20 at predetermined flow rates. The flow rates are predetermined to balance the flow of gases to the stations 20 by calibrating the valve systems 18 as described below.

Note that only four stations 20 and four valve systems 18 are shown for example only. In general, the tool 10 may comprise N stations 20 and N valve systems 18, where N is an integer greater than 2. The tool 10 further comprises a system controller 24. The system controller 24 controls the gas sources 12, the MFCs 16, the valve systems 18, and other components of the stations 20 and the tool 10. Examples of the other components of the stations 20 and the tool 10 are shown and described below with reference to FIG. 1C.

The tool 10 further comprises a plurality of sensors 30. The sensors 30 may be distributed throughout the tool 10. For example, the sensors 30 may be located downstream from the valve systems 18 (e.g., in the showerheads 22 and/or the stations 20). The sensors 30 provide feedback to the system controller 24 regarding gas flow in each of the stations 20. The system controller 24 uses the feedback to adjust the flow coefficients of the valves in the valve systems 18 to balance the gas flow across the stations 20.

Alternatively or additionally, the tool 10 may also comprise a metrology system 32. The metrology system 32 may analyze the substrates processed in the stations 20 and provide data indicative of flow imbalance between the stations 20. The system controller 24 uses the data to adjust the flow coefficients of the valves in the valve systems 18 to balance the gas flow across the stations 20. Note that these adjustments can be carried out as calibrations during manufacturing, installation, and/or preventive maintenance of the tool 10.

In FIG. 1B, the tool 11 comprises all of the elements of the tool 10 shown in FIG. 1A except that the tool 11 comprises separate MFCs 16-1, 16-2, 16-3, and 16-4 (collectively the MFCs 16) for each station 20. In the tool 11, each of the MFCs 16 is connected to the respective valve system 18 through respective manifolds. Otherwise, the description of the other elements of the tool 11 is identical to the description of the corresponding elements of the tool 10 shown in FIG. 1A. Therefore, the description of the other elements of the tool 11 is not repeated for brevity.

FIG. 1C shows an example of the tool 100 employing the valve system 18 of the present disclosure in further detail. Only one station 20 and one valve system 18 are shown for illustrative purposes. It is understood that the tool 100 comprises N stations 20 and N valve systems 18 connected to the N stations 20, respectively, where N is an integer greater than 2. The tool 100 comprises the system controller 24 that calibrates the valves in the N valve systems 18 to balance the gas flow across the N stations 20 as described below with reference to FIG. 3A onwards.

The tool 100 may process substrates in the stations 20 using various processes. For example, the processes may include atomic layer deposition (ALD), plasma enhanced ALD (PEALD), chemical vapor deposition (CVD), plasma-enhanced CVD (PECVD), and/or other deposition and etching processes. The description provided below with reference to the station 20 and the valve system 18 applies to all of the stations 20 and the valve systems 18 in the tool 100 and in the tools 10, 11 shown in FIGS. 1A and 1B.

The tool 100 comprises one or more gas delivery systems 120-1, 120-2, and so on (collectively gas delivery systems 120). The gas delivery systems 120 may include one or more gas sources 122-2, 122-2, . . . , and 122-N (collectively gas sources 122), where N is an integer greater than one. Valves 124-1, 124-2, . . . , and 124-N (collectively valves 124) and mass flow controllers 126-1, 126-2, . . . , and 126-N (collectively mass flow controllers 126) or other flow control devices may be used to controllably supply one or more gases to a manifold 130. A vaporized precursor delivery system 128 supplies a vaporized precursor to the manifold 130. The manifold 130 supplies a gas mixture to the valve system 18.

The valve system 18 is described in further detail with reference to FIG. 3A onwards. Briefly, the valve system 18 comprises a manifold block 132 and valves V1, V2, and V3. The valves V1, V2, and V3 respectively correspond to the first, second, and third valves described above. The manifold block 132 includes two inlets 140, 142 and two outlets 144, 146. The manifold block 132 receives process gases from the manifold 130 via the first inlet 140. In addition, the gas delivery system 120-2 supplies an inert gas to the manifold block 132 via the second inlet 142. The gas delivery system 120-2 supplies the inert gas to the manifold block 132 via a first manifold 134 and a second manifold 136. For example, the gas delivery system 120-2 supplies the inert gas through first manifold 134 throughout the process as trickle supply (described above). The gas delivery system 120-2 supplies the inert gas through the second manifold 136 during a purge step as burst supply (also described above). The outputs of the two manifolds 134, 136 are joined together to form a combined output. The combined output is connected to the second inlet 142 of the manifold block 132. In some examples, a single manifold may be used instead of the two manifolds 134, 136, and the single manifold may be connected to the second inlet 142 of the manifold block 132.

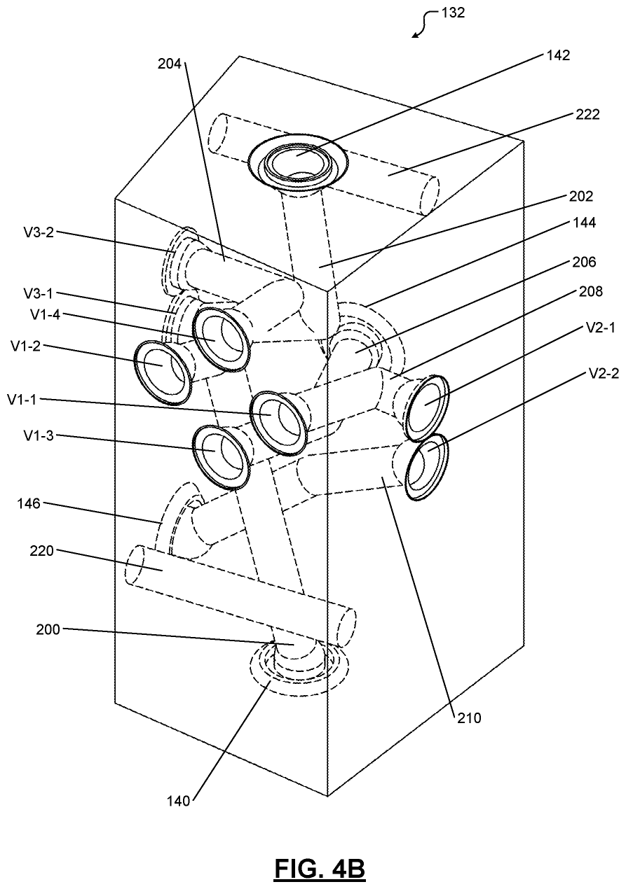

The valves V1, V2, and V3 are mounted to the manifold block 132. For example, the valve V1 is a four-port valve, and the valves V2 and V3 are two-port valves. The manifold block 132 comprises a plurality of gas flow channels, which are shown and described below in detail with reference to FIGS. 4A and 4B. The gas flow channels are connected to the valves V1, V2, and V3 and to the inlets 140, 142 and outlets 144, 146 of the manifold block 132. The valves V1, V2, and V3 control the flow of gases into the station 20. The valve V1 controls the flow of process gases into the station 20 during the dose step of the process. The valve V2 diverts process gases and prevents the diverted gases from entering the station 20 during the purge step of the process. The valve V3 controls the flow of the inert gas (both the trickle supply throughout the process and the burst supply during the purge step) into the station 20.

The valve system 18 supplies process gas mixtures to the station 20 using a gas distribution device such as the showerhead 22. In some examples, the showerhead 22 is a chandelier-type showerhead. In the station 20, a substrate 118 such as a semiconductor wafer may be arranged on a substrate support 116 during processing. The substrate support 116 may include a pedestal, an electrostatic chuck, a mechanical chuck, or other type of substrate support. While not shown, the showerhead 22 and the substrate support 116 may comprise heating and cooling systems that control the temperatures of the showerhead 22 and the substrate support 116 during processing of the substrate 118, cleaning of the station 20, and so on.

In some processes, plasma is struck by supplying RF power to the showerhead 22 with the substrate support 116 being grounded or floating. Alternatively, plasma can be struck by supplying the RF power to the substrate support 116 with the showerhead 22 being grounded or floating. An RF plasma generator 150 generates the RF power used to generate plasma in the station 20. The RF plasma generator 150 may be an inductive or capacitive-type RF plasma generator. For example, the RF plasma generator 150 may include an RF supply 152 that generates an RF voltage and a matching and distribution network 154 that supplies the RF voltage to the showerhead 22 or the substrate support 116. Alternatively, plasma may be generated remotely from (i.e., external to) the station 20 and may be supplied to the stations 20.

The system controller 24 monitors process parameters such as temperature, pressure, etc. (using one or more sensors 30) and controls process timing in the station 20. The system controller 24 controls the components of the tool 100 such as the gas delivery systems 120, the heating and cooling systems in the showerhead 22 and the substrate support 116, the RF plasma generator 150, and the valve system 18. The system controller 24 also controls a valve 160 and pump 162, which are used to control pressure in the station 20 and to evacuate the station 20.

FIGS. 2A and 2B show a valve system 19 with only the valves V1 and V2 and without the valve V3. FIG. 2A shows a block diagram of the valve system 19. FIG. 2B shows a schematic of the valve system 19. In FIG. 2A, the valve system 19 includes a manifold block 133 with the valves V1 and V2 mounted to the manifold block 133. The manifold block 133 has two inlets 140, 142 and two outlets 144, 146 similar to the manifold block 132. The manifold block 133 is connected to the manifolds 130, 134, 136 similar to the manifold block 132.

In FIG. 2B, the valve V1 is a 4-port valve, and the valve V2 is a 2-port valve. The port numbers of the valves V1 and V2 are identified by numbers 1, 2, 3, and 4. The valve V2 is a normally closed valve (shown as NC). The manifold block 133 includes gas flow channels that connect the ports of the valves V1 and V2 to the inlets 140, 142 and the outlets 144, 146 as shown. When the valve system 19 is used in the tools shown in FIGS. 1A-1C, without the valve V3, the flow of inert gas is not balanced across the stations 20. The flow imbalance causes the process non-uniformities and plasma instability as described above.

Specifically, in the tools 10, 11, and 100 shown in FIGS. 1A-1C, if the two-valve system 19 shown in FIGS. 2A and 2B is used instead of the three-valve systems 18, when the stations 20 perform the same process on the substrates, station-to-station process non-uniformities and plasma instability may occur. The non-uniformities and plasma instability can occur due to flow imbalance in the stations 20 caused by factors such as manufacturing variations in the components of the gas delivery systems. For example, it is very difficult to perfectly match the dimensions of the various conduits, valves, and manifolds used to supply gases to each station. By using the valve systems 18, station-to-station flow balancing is achieved by individually controlling the flow coefficient of the valve V3 in each of the valve systems 18. Specifically, the flow coefficient of the valve V3 in each of the valve systems 18 is adjusted to compensate for the manufacturing variations in the components of the gas delivery systems used with the stations 20. The flow coefficient of the valve V3 in each of the valve systems 18 is adjusted such that the flow of the inert gas to the stations 20 is balanced. Therefore, when the stations 20 perform the same process on the substrates, the station-to-station process non-uniformities and plasma instability are significantly reduced irrespective of the manufacturing variations.

A flow coefficient Cᵥ of a flow control device such as the valve V3 is a relative measure of efficiency of the flow control device in allowing fluid flow. The flow coefficient Cᵥ describes a relationship between a pressure drop across the flow control device and corresponding flow rate. The flow coefficient Cᵥ (i.e., a flow-capacity rating of a valve) can be expressed by the following equation:

$${C}_{v} = Q \sqrt{\frac{SG}{Δ P}}$$

where Q is the rate of flow of a fluid, SG is a specific gravity of the fluid, and ΔP is a pressure drop across the valve.

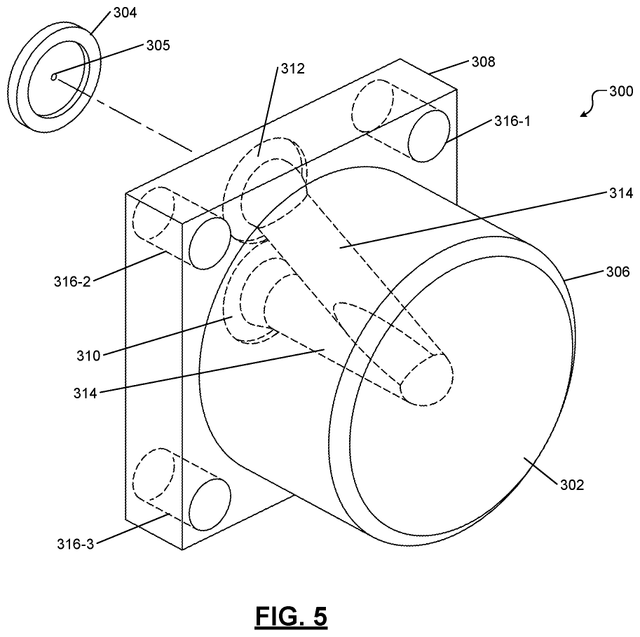

Flow coefficients can be used to compare valve capacities and to size valves. The system controller 24 can be used to control the Cᵥ of each of the valves V3 in the valve systems 18 to compensate for manufacturing variations and to balance the flow of inert gas between the stations 20. Alternatively, if the required Cᵥ value for a station is known, the valve V3 can be replaced by a flow-through cap-and-orifice assembly, which is shown and described below with reference to FIG. 5. In the cap and orifice assembly, the dimensions of orifice are designed (i.e., selected) to provide the required Cᵥ value. That is, the orifice is selected with dimensions that will supply the inert gas to the station 20 at the required Cᵥ value. Balancing the flow of inert gas across the stations 20 using the valve V3 or the cap and orifice assembly makes the stations 20 perform uniformly with respect to process non-uniformities and plasma instability. The valve V3 and the cap and orifice assembly can be generally called flow control devices.

The valves V3 in each of the valve systems 18 can be calibrated (e.g., the Cᵥ values of the valves V3 in each of the valve systems 18 can be set) empirically. The valves V3 can be calibrated during the manufacturing of the tool and/or at the time of setting up the tool on site. That is, based on requirements of a process to be performed on the substrates in the stations 20, the flow of the inert gas to be supplied to the stations 20 via the valves V3 in the valve systems 18 can be individually adjusted to achieve flow balance across the stations 20. The adjustments of Cᵥ values of the valves V3 in each of the valve systems 18 compensate for the manufacturing variations that may inevitably occur in the manufacture of the components of the gas delivery systems. Due to the adjustments, the flow of inert gas to each of the stations 20 can be individually controlled to compensate for the manufacturing variations.

Further, the valves V3 can be re-calibrated during preventive maintenance of the tools as needed. Furthermore, the valves V3 can also be adjusted during runtime (i.e., while the process is running). For example, the system controller 24 may receive feedback from the sensors 30. The feedback from the sensors 30 may be indicative of non-uniformities and plasma instability that may be occurring in one station but not in other stations of the tool. The system controller 24 can adjust the Cᵥ of the valve V3 associated with that station based on the feedback from the sensors 30.

Alternatively or additionally, the system controller 24 may receive data from an in-situ (or external) metrology system 32 as feedback. While not shown in FIG. 1C to simplify illustration of the other elements of the tool 100, the system controller 24 shown in FIG. 1C also communicates with the metrology system 32 (shown in FIGS. 1A and 1B). For example, the metrology system 32 may measure a property of the substrate processed in a station. For example, the metrology system 32 may measure thickness of a film deposited on the substrate by a process in a station. The data from the metrology system 32 may indicate variations in a substrate processed using a process in one station compared to a substrate processed using the same process in another station. Based on the data from the metrology system 32, the system controller 24 can adjust the Cᵥ of the valve V3 associated with the station in which the property of the substrate indicates a variation. The variation may occur although the same process is used to process the substrate in each of the stations 20. By adjusting the Cᵥ of the valve V3 associated with the station in which the variation is occurring, the flow of inert gas to each of the stations 20 can be balanced, and the variation can be alleviated.

FIGS. 3A and 3B show the valve system 18 in further detail. FIG. 3A shows a block diagram of the valve system 18. FIG. 3B shows a schematic of the valve system 18. In FIG. 3A, the valve system 18 includes the manifold block 132 with the valves V1, V2, and V3 mounted to the manifold block 132. The manifold block 132 has the two inlets 140, 142 and the two outlets 144, 146. The manifold block 132 is connected to the manifolds 130, 134, 136.

In FIG. 3B, the valve V1 is a 4-port valve, and the valves V2 and V3 are 2-port valves. The port numbers of the valves V1, V2, and V3 are identified by numbers 1, 2, 3, and 4. The valves V2 and V3 are normally closed valves (shown as NC). While specific types of valves are shown, other types of valves that can provide the described functionality can be used instead.

The manifold block 132 includes gas flow channels that connect the ports of the valves V1, V2, and V3 to the inlets 140, 142 and the outlets 144, 146 as shown. The gas flow channels of the manifold block 132 are shown and described below in detail with reference to FIGS. 4A and 4B. When the valve systems 18 are used in the tools 10, 11, 100 shown in FIGS. 1A-1C, and the Cᵥ's of the valves V3 are calibrated as described above, and the flow of inert gas is balanced across the stations 20, which minimizes the process non-uniformities and plasma instability as described above.

FIGS. 4A and 4B show the gas flow channels within the manifold block 132 and their connections to the valves V1, V2, V3 and to the inlets 140, 142 and the outlets 144, 146. FIG. 4A shows the gas flow channels without heaters. FIG. 4B shows the gas flow channels with heaters. In the description below, the gas flow channels are simply called gas channels.

In FIG. 4A, the manifold block 132 includes six gas channels. A first gas channel 200 extends from the first inlet 140 of the manifold block 132 to the second port V1-2 of the 4-port valve V1. A second gas channel 202 extends from the second inlet 142 of the manifold block 132 to the first port V3-1 of the 2-port valve V3. A third gas channel 204 connects the second port V3-2 of the 2-port valve V3 to the fourth port V1-4 of the 4-port valve V1. A fourth gas channel 206 connects the third port V1-3 of the 4-port valve V1 to the first outlet 144. A fifth gas channel 208 connects the first port V1-1 of the 4-port valve V1 to the first port V2-1 of the 2-port valve V2. A sixth gas channel 210 connects the second port V2-2 of the 2-port valve V2 to the second outlet 146. The gas flow channels of the manifold block 132 are designed such that the manifold block 132 does not increase dead leg volume between the manifolds 130, 134, 136 and the showerhead 22 of the station 20.

The system controller 24 controls the valves V1, V2, and V3 to supply the process gases and the inert gas from the manifolds 130, 134, 136 to the showerhead 22 of the station 20 during dose and purge steps. Specifically, during the dose step, the valve V1 is open (i.e., the port V1-1 is in fluid communication with the port V1-3), the valve V2 is closed, and the valve V3 is open. The precursor from the manifold 130 enters the manifold block 132 via the first inlet 140, flows through the first gas channel 200 into the port V1-2, flows through the ports V1-1 and V1-3 into the fourth gas channel 206, and flows through the first outlet 144 into the showerhead 22.

Additionally, since the valve V3 is open during the dose step, the trickle supply of the inert gas from the first manifold 134 enters the manifold block 132 through the second inlet 142, flows into the second gas channel 202, flows through the ports V3-1 and V3-2 into the third gas channel 204, flows through the ports V1-4 and V1-3 into the fourth gas channel 206, and flows through the first outlet 144 into the showerhead 22. Since the valve V2 is closed, neither the precursor nor the inert gas flows through the valve V2 and through the sixth gas channel 210 into the second outlet 146 of the manifold block 132.

During the purge step, the valve V1 is closed (i.e., the port V1-1 is not in fluid communication with the port V1-3), and the valves V2 and V3 are open. The burst supply of the inert gas from the second manifold 136 enters the manifold block 132 through the second inlet 142 into the second gas channel 202, flows through the ports V3-1 and V3-2 into the third gas channel 204, flows through the ports V1-4 and V1-3 into the fourth gas channel 206, and flows through the first outlet 144 into the showerhead 22. Since the valve V1 is closed (i.e., the port V1-1 is not in fluid communication with the port V1-3), the precursor does not flow into the showerhead 22 during the purge step. Further, since the valve V2 is open, the residual precursor in the fifth gas channel 208 from the prior dose step is diverted through the valve V2, through the sixth gas channel 210, and through the second outlet 146.

In both dose and purge steps, the calibrated Cᵥ settings of the valves V3 in each of the valve systems 18 ensure that the flow of inert gas to the stations 20 is balanced regardless of manufacturing variations of the components of the gas delivery systems used to supply the various gases to the stations 20.

In FIG. 4B, the manifold block 132 is shown with two heaters 220, 222. Other than the addition of the heaters 220, 222, the manifold block 132 shown in FIG. 4B is identical to FIG. 4A. Accordingly, the description of FIG. 4A applies equally to FIG. 4B and is not repeated for brevity. While two heaters are shown for example only, any number of heaters (e.g., one, three, four, or more) may be used instead. The heaters 220, 222 prevent condensation around the gas flow channels of the manifold block 132. The system controller 24 shown in FIGS. 1A-1C controls the power supply to the heaters 220, 222. For example, the heaters 220, 222 may include cartridge heaters. Alternatively, while not shown, the heaters 220, 222 may include jacket heaters.

FIG. 5 shows a flow-through cap-and-orifice assembly 300 that can be used instead of the valve V3 in the valve systems 18. The flow-through cap-and-orifice (hereinafter the cap and orifice assembly) 300 can be used along with the valves V1 and V2 and the manifold block 132 to achieve the flow balancing. The cap and orifice assembly 300 can be used if a required Cᵥ value for a station is known. The dimensions of the orifice in the cap and orifice assembly 300 can be selected to supply the inert gas during both trickle and burst supplies at the required Cᵥ value.

The cap and orifice assembly 300 is mounted to the manifold block 132 in place of the valve V3. The cap and orifice assembly 300 comprises a cap 302 and an orifice plate 304. The cap 302 includes a cup-shaped cylindrical portion 306 connected to a mounting plate 308 that mounts to the manifold block 132. The mounting plate 308 includes an inlet 310 and an outlet 312. The mounting plate 308 is mounted to the manifold block 132 using a plurality of fasteners 316-1, 316-2, 316-3, 316-4 (not visible). When mounted, the inlet 310 and the outlet 312 are respectively connected to the manifold block 132 at locations where the ports V3-1 and V3-2 of the valve V3 are connected to the manifold block 132.

The orifice plate 304 is a disc shaped structure with an orifice 305 at the center of the orifice plate 304. The dimensions of the orifice 305 can be selected to provide a predetermined Cᵥ required for the station 20. The orifice plate 304 is mounted to the outlet 312 of the cap and orifice assembly 300. The cylindrical portion 306 includes a gas flow channel 314 that connects the inlet 310 of the cap and orifice assembly 300 to the outlet 312 of the cap and orifice assembly 300.

In use, the inert gas flows into the cap and orifice assembly 300 through the inlet 310, into the gas flow channel 314, and flows into the manifold block 132 through the outlet 312 at a predetermined Cᵥ through the orifice 305. The cap and orifice assembly 300 can be installed on the manifold block 132 associated with any of the stations 20. The dimensions of the orifice 305 are selected to provide the predetermined Cᵥ required for that station 20. The Cᵥ required for a process for the station 20 can be empirically determined after all of the components of the gas delivery systems for the stations 20 are installed. By using the orifice 305 having the specific dimensions for each station, the flow of inert gas is balanced across the stations 20 irrespective of the manufacturing variations of the components of the gas delivery systems used with the stations 20.

When the cap and orifice assembly 300 is used with the manifold block 132, the flow of gases through the manifold block 132 and the valves V1 and V2 is identical to that described above with reference to FIG. 4A. The flow of gases is identical because similar to the valve V3, which is open during the dose and purge steps, the orifice 305 is open during both steps. The selected dimensions of one or more orifices 305 used with respective valve systems 18 ensure that the flow of inert gas to the stations 20 is balanced regardless of manufacturing variations in the components of the gas delivery systems used to supply the various gases to the stations 20.

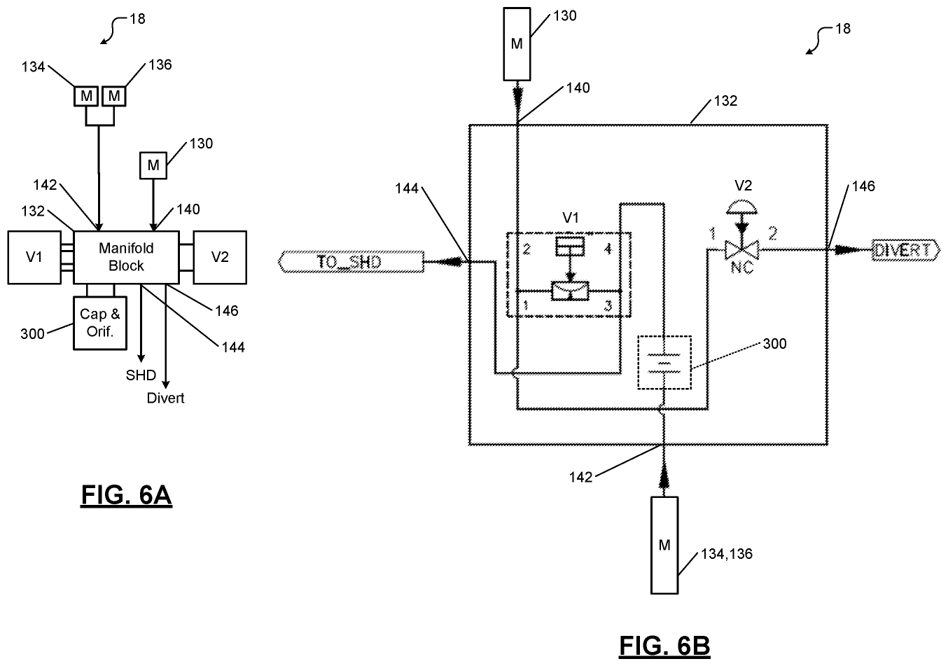

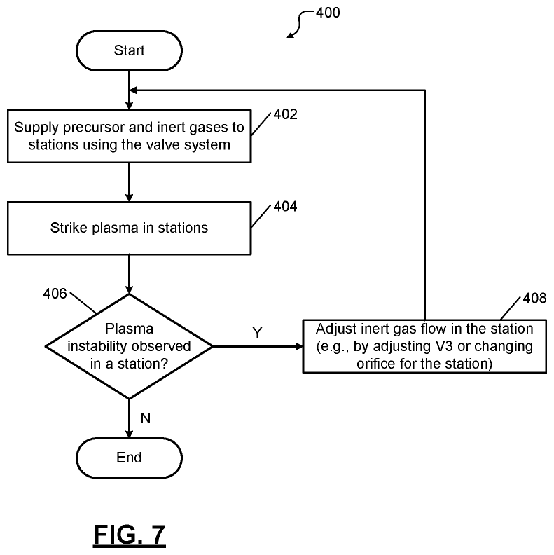

FIGS. 6A and 6B show the valve system 18 including the cap and orifice assembly 300 in further detail. FIG. 6A shows a block diagram of the valve system 18 including the cap and orifice assembly 300 instead of the valve V3. FIG. 6B shows a schematic of the valve system 18 including the cap and orifice assembly 300 instead of the valve V3. Except for the replacement of the valve V3 with the cap and orifice assembly 300, FIG. 6A is identical to FIG. 3A. Therefore, FIG. 6A is not described in further detail for brevity.

In FIG. 6B, as in FIG. 3B, the valves V1 and V2 are 4-port and 2-port valves, respectively, although other types of valves that provide the described functionality can be used instead. The port numbers of the valves V1 and V2 are identified by numbers 1, 2, 3, and 4. The valve V2 is a normally closed valve (shown as NC). The cap and orifice assembly 300 is mounted to the manifold block 132 instead of the valve V3. The manifold block 132 includes gas flow channels that connect the ports of the valves V1 and V2 and the cap and orifice assembly 300 to the inlets 140, 142 and the outlets 144, 146 as shown. The gas flow channels of the manifold block 132 are the same as those shown and described above with reference to FIGS. 4A and 4B and are therefore not described again for brevity. When the valve systems 18 are used in the tools 10, 11, 100 shown in FIGS. 1A-1C, and the dimensions of the orifices 305 are selected according to the known Cᵥ values of the stations 20, the flow of inert gas is balanced across the stations 20, which minimizes the process non-uniformities and plasma instability as described above.

FIG. 7 shows a method 400 performed by the system controller 24 to balance the flow of inert gas across the stations 20. Note that the system controller 24 can perform the method 400 before installation of (i.e., during manufacture of) a tool, at the time of installing the tool, during preventive maintenance of the tool, and/or while a process is being performed in the stations 20. While the orifice 305 can be sized and selected during manufacture, setup, and preventive maintenance, the orifice 305 cannot be replaced while a process is being performed in the stations 20. In contrast, the Cᵥ of the valve V3 can be adjusted during any of these procedures.

At 402, the method 400 supplies process gases and inert gases to the stations 20 using the valve systems 18 connected to the stations 20, respectively. At 404, the method 400 strikes plasma in the stations 20. At 406, the method 400 determines if plasma instability and or other process non-uniformities are detected in one or more stations. For example, the plasma instability (and/or a non-uniformity) can be detected based on data from one or more sensors 30 and/or data from the metrology system 32. If plasma instability (and/or a non-uniformity) is not detected in any of the stations 20, the method 400 ends.

If plasma instability (and/or a non-uniformity) is detected in any of the stations 20, at 408, the method 400 adjusts the Cᵥ of the valve V3 in the valve system 18 corresponding to the station or stations 20 in which plasma instability (and/or a non-uniformity) is detected. Alternatively, if a cap and orifice assembly 300 is used instead of the valve V3, a different orifice 305 having a different dimension suitable for supplying the inert gas to the station 20 at the predetermined Cᵥ value required for the station 20 is selected. Subsequently, the method 400 returns to 402.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers. As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate processing system comprising:
N stations configured to perform a process on substrates, where N is an integer greater than 1; and
N valve systems connected to the N stations, respectively;
wherein each of the N valve systems comprises:
a manifold block comprising inlets to receive a process gas and an inert gas, an outlet connected to one of the N stations, and a plurality of gas flow channels disposed within the manifold block and connected to the inlets and the outlet;
a plurality of valves mounted to the manifold block and configured to control flow of the process gas and the inert gas through the outlet; and
a flow control device mounted to the manifold block and configured to control flow of the inert gas through the manifold block into the one of the N stations; and
wherein the flow control device of each of the N valve systems is calibrated to balance the flow of the inert gas in the N stations.

2. The substrate processing system of claim 1 wherein the flow control device includes a 2-port valve and wherein a flow coefficient of the 2-port valve in each of the N valve systems is calibrated to balance the flow of the inert gas in the N stations.

3. The substrate processing system of claim 1 wherein the flow control device includes a flow-through cap-and-orifice assembly and wherein an orifice in the flow-through cap-and-orifice assembly is designed to balance the flow of the inert gas in the N stations.

4. The substrate processing system of claim 1 further comprising a controller configured to calibrate the flow control device in each of the N valve systems to balance the flow of the inert gas in the N stations.

5. The substrate processing system of claim 1 further comprising:
N sensors configured to sense gas flow from the N valve systems into the N stations, respectively; and
a controller configured to calibrate the flow control device in at least one of the N valve systems based on data received from at least one of the N sensors to balance the flow of the inert gas in the N stations.

6. The substrate processing system of claim 1 further comprising:
a metrology system configured to analyze one or more of the substrates processed in one or more of the N stations; and
a controller configured to calibrate the flow control device in at least one of the N valve systems based on data received from the metrology system to balance the flow of the inert gas in the N stations.

7. The substrate processing system of claim 1 wherein the manifold block comprises a second outlet and wherein one of the valves is configured to selectively divert one or more gases from the manifold block through the second outlet during a step of the process.

8. The substrate processing system of claim 1 wherein the flow control device in each of the N valve systems is configured to control the flow of the inert gas that is supplied to each of the N stations at a plurality of flow rates.

9. The substrate processing system of claim 1 wherein the flow control device in each of the N valve systems is configured to control the flow of the inert gas that is supplied to each of the N stations uninterruptedly at a first rate and periodically at a second rate greater than the first rate.

10. The substrate processing system of claim 1 wherein the valves comprise a 4-port valve and a 2-port valve and wherein the flow control device comprises a 2-port valve.

11. The substrate processing system of claim 1 wherein the valves comprise a 4-port valve and a 2-port valve and wherein the flow control device comprises a flow-through cap-and-orifice assembly.

12. The substrate processing system of claim 1 wherein the process includes an atomic layer deposition process and wherein the flow control device is configured to control the flow of the inert gas during dose and purge steps of the atomic layer deposition process.

13. A substrate processing system comprising:
N stations configured to perform an atomic layer deposition process on substrates, where N is an integer greater than 1;
N valve systems connected to the N stations, respectively;
wherein each of the N valve systems comprises:
a manifold block comprising inlets to receive a process gas and an inert gas, an outlet connected to one of the N stations, and a plurality of gas flow channels disposed within the manifold block and connected to the inlets and the outlet;
a plurality of valves mounted to the manifold block and configured to control flow of the process gas and the inert gas through the outlet; and
a flow control device mounted to the manifold block and configured to control flow of the inert gas through the manifold block into the one of the N stations; and
a controller configured to calibrate the flow control device in each of the N valve systems to balance the flow of the inert gas in the N stations during dose and purge steps of the atomic layer deposition process.

14. The substrate processing system of claim 13 wherein the flow control device includes a 2-port valve and wherein a flow coefficient of the 2-port valve in each of the N valve systems is calibrated to balance the flow of the inert gas in the N stations.

15. The substrate processing system of claim 13 wherein the flow control device includes a flow-through cap-and-orifice assembly and wherein an orifice in the flow-through cap-and-orifice assembly is designed to balance the flow of the inert gas in the N stations.

16. The substrate processing system of claim 13 further comprising:
N sensors configured to sense gas flow from the N valve systems into the N stations, respectively; and
wherein the controller is configured to calibrate the flow control device in at least one of the N valve systems based on data received from at least one of the N sensors to balance the flow of the inert gas in the N stations.

17. The substrate processing system of claim 13 further comprising:
a metrology system configured to analyze one or more of the substrates processed in one or more of the N stations; and
wherein the controller is configured to calibrate the flow control device in at least one of the N valve systems based on data received from the metrology system to balance the flow of the inert gas in the N stations.

18. The substrate processing system of claim 13 wherein the manifold block comprises a second outlet and wherein one of the valves is configured to selectively divert one or more gases from the manifold block through the second outlet during the purge step of the atomic layer deposition process.

19. The substrate processing system of claim 13 wherein the flow control device in each of the N valve systems is configured to control the flow of the inert gas that is supplied to each of the N stations at a plurality of flow rates during the dose and purge steps.

20. The substrate processing system of claim 13 wherein the flow control device in each of the N valve systems is configured to control the flow of the inert gas that is supplied to each of the N stations uninterruptedly at a first rate during the dose step and purge steps and at a second rate greater than the first rate during the purge step.

21. The substrate processing system of claim 13 wherein the valves comprise a 4-port valve and a 2-port valve and wherein the flow control device comprises a 2-port valve or a flow-through cap-and-orifice assembly.
